(19) United States
(12) Patent Application Publication
(10) Pub. No.: US 2003/0217697 A1
(43) Pub. Date: Nov. 27, 2003

(54) Liquid material evaporation supply apparatus

(76) Inventors: Hideaki Miyamoto, Kyoto (JP); Hitoshi Kitagawa, Kyoto (JP); Tetsuo Shimizu, Kyoto (JP)

Correspondence Address: SNELL & WILMER LLP, 1920 MAIN STREET, SUITE 1200, IRVINE, CA, 92614-7230, US

(21) Appl. No.: 10/385,907

(22) Filed: Mar. 11, 2003

(30) Foreign Application Priority Data
Mar. 13, 2002 (JP) 2002-069131

(51) Int. Cl. C23C 16/00

(52) U.S. Cl. 118/715

(57) ABSTRACT

A liquid material evaporation supply apparatus is provided with a material tank which accommodates a liquid material heated to generate a predetermined gas, a liquid material supply pipe for supplying the liquid material to the material tank, and a gas discharge pipe for discharging the gas generated in the material tank. A heating device for heating exclusively the material tank is provided on the material tank. A preheat device preheats the liquid material that supplied to the material tank and a liquid flow regulation device for regulating the flow rate of the liquid material that is to be supplied to the material tank is also heated. A gas flow meter connected to the gas discharge pipe is also heated whereby a thermostatic chamber is not required.

### BACKGROUND OF THE INVENTION

1. Field of the Invention

The present invention relates to a liquid material evaporation supply apparatus for supplying various gasses, for example, employed in semiconductor manufacturing by evaporating a liquid material and more particularly a compact evaporation supply system that maintains a constant supply of gas.

2. Description of the Related Art

There is a conventional liquid material evaporation supply apparatus in which a material tank for heating and evaporating a liquid material in a thermostatic chamber and a mass flow controller for controlling the flow rate of the gas generated in the material tank are provided. FIG. 3 schematically shows such a liquid material evaporation supply apparatus. In this drawing, the reference numeral 31 denotes the thermostatic chamber in which an appropriate temperature is set, and a material tank 33 which accommodates the liquid material LM inside and which is provided with a heater 32 for heating the liquid material LM is provided. A liquid material supply pipe 34 for supplying the liquid material LM and a gas discharge pipe 35 for discharging the gas generated in the material tank 33 are connected to the material tank 33. An on-off valve 36 is provided on the liquid material supply pipe 34, and a mass flow controller 37 for high temperature service is provided on a portion of the gas discharge pipe 35 inside the thermostatic chamber 31.

In the liquid material evaporation supply apparatus of such a structure, when the material tank 33 accommodating the liquid material LM is heated by the heater 32, the inside temperature of the tank increases so that the vapor pressure of the liquid material LM is increased, and thus the liquid material LM is evaporated to become a predetermined gas. This generated gas is discharged to the outside by obtaining a pressure differential between the material tank 33 and the gas discharge pipe 35 while flow control is directly executed by the high-temperature mass flow controller 37. The generated gas is sent in a direction toward a use point (e.g., a semiconductor manufacturing apparatus) that is not shown.

In the liquid material evaporation supply apparatus shown in FIG. 3, the flow rate of the liquid material LM inside the material tank 33 is detected by a level gage which is not shown and in which a float is employed. When the volume of the liquid material LM becomes smaller than a predetermined volume, the on-off valve 36 provided on the liquid material supply pipe 34 is opened so that liquid material LM can be supplied to the material tank 33. In this case, the temperature of the liquid material LM inside the material tank 33 decreases due to the new supplied liquid material LM so that a desired constant gas generation is not maintained, gas generation is interrupted every time the liquid material LM is supplied, and thus there is an inconvenience that evaporation gas cannot be continuously generated and cannot be continuously supplied.

In the case where flow control of the gas is performed by means of a high-temperature mass flow controller 37, there is also a need to replace heat due to adiabatic expansion in a control valve portion, thus, it is necessary to set the temperature of the high-temperature mass flow controller 37 to a temperature approximately 10° C. higher than the temperature in the material tank 33. The temperature of a flow sensor portion incorporated in the high-temperature mass flow controller 37 is relatively high with this setting, and as a result, there is an inconvenience that stability and reliability in the flow control for the generated gas due to the high-temperature mass flow controller 37 may be deteriorated.

Further, in the conventional liquid material evaporation supply apparatus, since the material tank 33 and the high-temperature mass flow controller 37 are accommodated in the thermostatic chamber 31, there is a structural inconvenience in that the entire apparatus has to be large. Thus there is a need for an improved gas supply apparatus in this field.

### SUMMARY OF THE INVENTION

The present invention has been made while attention is directed to the above described matters, and it is an object of the present invention to provide a compact liquid material evaporation supply apparatus with high reliability in which evaporation gas can be continuously generated and in which flow control for the generated evaporation gas can be performed with high accuracy and high stability.

In order to achieve the above-described object, a liquid material evaporation supply apparatus is provided with a material tank which accommodates a liquid material which is heated to generate a predetermined gas. A liquid material supply pipe for supplying the liquid material to the material tank, a gas discharge pipe for discharging the gas generated in the material tank, and a heating device for heating exclusively the material tank is provided on the material tank. A preheat device for preheating the liquid material that is to be supplied to replenish the material tank and a liquid flow regulation device for regulating the flow rate of the liquid material that is to be supplied to the material tank are further provided on the liquid material supply pipe.

Since the liquid material that is to be supplied to the material tank is preheated before being supplied thereto, and since the amount of supply thereof is restricted, evaporation inside the material tank is not adversely affected, and the liquid material can be supplied even while evaporation gas is being generated. Since a heating device is provided on the material tank exclusively therefore, a thermostatic chamber is not necessary.

In a liquid material evaporation supply apparatus provided with a material tank which accommodates a liquid material and in which the liquid material is heated to generate a predetermined gas, a liquid material supply pipe for supplying the liquid material to the material tank, and a gas discharge pipe for discharging the gas generated in the material tank, a heating device for heating exclusively the material tank is provided on the material tank, a gas flow meter and a gas flow control valve are mutually independently provided on the gas discharge pipe, and the temperatures of the gas flow meter and the gas flow control valve are individually controlled.

The temperature of the gas flow control valve can be set to a temperature for example approximately 10° C. higher than that of the material tank in order to compensate from the loss of any heat due to adiabatic expansion. In this case, the temperature of the gas flow meter can be set to a temperature of about 5 to 8° C. lower than that of the gas flow control valve. Accordingly, the evaporation gas can be measured with high precision, and the flow rate thereof can be controlled with high precision. Since a heating device is provided on the material tank exclusively therefore, a thermostatic chamber is not necessary.

Further, in a liquid material evaporation supply apparatus provided with a material tank which accommodates a liquid material and in which the liquid material is heated to generate a predetermined gas, a liquid material supply pipe for supplying the liquid material to the material tank, and a gas discharge pipe for discharging the gas generated in the material tank, a heating device for heating exclusively the material tank is provided on the material tank, a preheat device for preheating the liquid material that is to be supplied to the material tank and a liquid flow regulation device for regulating the flow rate of the liquid material that is to be supplied to the material tank are provided on the liquid material supply pipe, a gas flow meter and a gas flow control valve are mutually independently provided on the gas discharge pipe, and the temperatures of the gas flow meter and the gas flow control valve are individually controlled.

### BRIEF DESCRIPTION OF THE DRAWINGS

The objects and features of the present invention, which are believed to be novel, are set forth with particularity in the appended claims. The present invention, both as to its organization and manner of operation, together with further objects and advantages, may best be understood by reference to the following description, taken in connection with the accompanying drawings.

FIG. 1 is a view schematically illustrating one example of the structure of a liquid material evaporation supply apparatus according to the present invention.

FIG. 2 is a view schematically illustrating another example of the structure of the liquid material evaporation supply apparatus.

FIG. 3 is a view for explaining the prior art.

### DETAILED DESCRIPTION OF THE PREFERRED EMBODIMENTS

The following description is provided to enable any person skilled in the art to make and user the invention and sets forth the best modes contemplated by the inventors of carrying out their invention. Various modifications, however, will remain readily apparent to those skilled in the art, since the general principles of the present invention have been defined herein specifically to provide a liquid material evaporation supply apparatus without a thermostatic chamber.

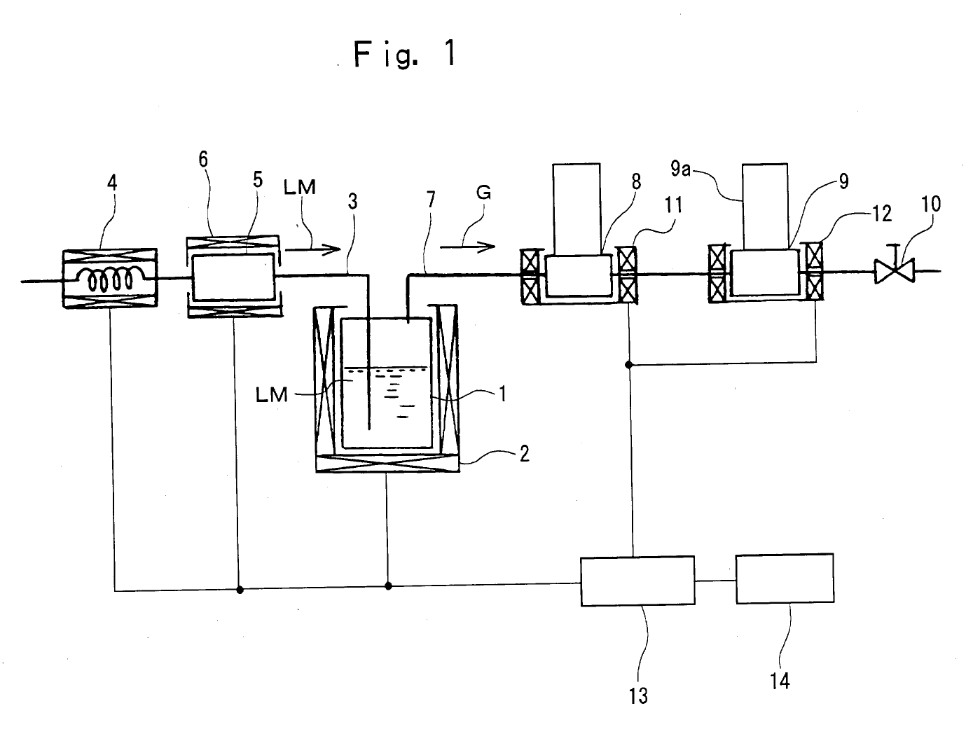

Details of the present invention are explained below by referring to the drawings. FIG. 1 schematically illustrates one example of the structure of a liquid material evaporation supply apparatus of the present invention. In this drawing, the reference numeral 1 denotes a material tank which accommodates a liquid material LM, and a heater 2 as a heating device is provided for example on the entire periphery except the upper surface of the material tank so as to heat the tank and keep it warm exclusively so that the liquid material LM accommodated inside the tank is heated to a predetermined temperature to generate an evaporation gas G. A suitable liquid level sensor is provided in the material tank 1 although the drawing thereof is omitted, and when the liquid level of the liquid material LM decreases to a predetermined liquid level, this condition is detected by the sensor so that a material replenishment signal is outputted.

The reference numeral 3 denotes a liquid material supply pipe for supplying the liquid material LM to the material tank 1. A preheat device 4 for preheating the liquid material LM that is to be supplied to the material tank 1 and a liquid flow regulation device 5 for regulating the flow rate of the liquid material LM are arranged for example in series in this order. An upstream side of the liquid material supply pipe 3 with respect to the preheat device 4 is connected to a liquid material supply source (not shown) accommodating the liquid material LM via appropriate piping. The preheat device 4 is for example composed of a first heater unit, which can be wound around the outer periphery of the liquid material supply pipe 3. Other forms of heaters can be used. The liquid flow regulation device 5 is for example composed of a mass flow controller for liquid and is heated and kept warm to a predetermined temperature by means of a heating device 6 such as a second heater unit.

The reference numeral 7 denotes a gas discharge pipe for discharging the evaporation gas G generated in the material tank 1, and a gas flow meter 8, a gas flow control valve 9, and an on-off valve 10 are arranged for example in this order in a mutually independent state. A downstream side of the gas discharge pipe 7 with respect to the on-off valve 10 is connected to a use point (not shown) via appropriate piping. The gas flow meter 8 is for example composed of a mass flow meter for gas, and is heated and kept warm to a predetermined temperature by means of a heating device 11 such as a third heater unit. The gas flow control valve 9 is for example composed of a control valve for a gas such as a piezo valve through which the valve opening is controlled by a piezo actuator 9a and is heated and kept warm to a predetermined temperature by means of a heating device 12 such as a fourth heater unit.

The reference numeral 13 indicates a temperature controller for individually controlling temperatures of each of the heater units, such as the heating device 2 for the material tank 1, the preheat device 4 provided on the liquid material supply pipe 3 for the liquid material LM, the heating device 6 for the liquid flow regulation device 5, the heating device 11 for the gas flow meter 8, and the heating device 12 for the gas flow control valve 9. The temperature controller 13 controls the temperatures of the respective heating devices 2, 4, 6, 11, 12 based on a command from a personal computer 14 which acts as a control device for controlling the entire liquid material evaporation supply apparatus. Temperature sensors (not shown) can monitor the temperature of each heating unit and provide appropriate temperature signals to the temperature controller. The individual heating units can be independently driven to a pre-determined temperature in comparison with the temperature signals depending on the characteristics of the liquid material and the flow rates. The personal computer 14, to which detection outputs from the liquid flow regulation device 5 and the gas flow meter 8 are inputted, performs predetermined calculations based on these outputs to find a desired liquid flow rate and a gas flow rate. The personal computer 14 has a function of outputting a predetermined control signal to the liquid flow regulation device 5 and the gas flow control valve 9 based on the calculation results, and a function of outputting a predetermined opening signal to the liquid flow regulation device 5 based on a detection signal from the liquid level sensor provided in the material tank 1. The temperature controller 13 and personal computer 14 can be combined into a dedicated controller unit as an alternative embodiment.

Next, operation of the liquid material evaporation supply apparatus of the structure described above is explained. When the liquid material LM inside the material tank 1 is heated to generate evaporation gas G, in order to continuously and stably generate a desired quantity of gas G so that evaporation is performed in the most suitable condition in accordance with the type of the liquid material LM, a heating temperature T° C. of the material tank 1 is set. At this time, the temperature of the preheat device 4 provided on the liquid material supply pipe 3 is set to a degree through which evaporation of the liquid material LM in the material tank 1 is not disturbed even when a quantity of the liquid material LM preheated by the preheat device 4 is supplied to the inside of the material tank 1. The liquid mass flow controller 5 device provided on the liquid material supply pipe 3 is heated and kept warm by the heating device 6 at a temperature in which the temperature of the liquid material LM is not decreased. The temperature of the piezo valve 9 which acts as a gas flow control valve provided on the gas discharge pipe 7 is heated and kept warm to a temperature approximately 10° C. higher than the set temperature T° C. for the material tank 1 in order to compensate for the loss of any heat due to adiabatic expansion. The gas flow meter 8 provided on the gas discharge pipe 7 is also heated and kept warm to a temperature about 5 to 8° C. lower than the set temperature for the gas flow control valve 9.

In such a liquid material evaporation supply apparatus, the liquid flow regulation device 5 is usually maintained in a closed condition. In this state, by heating the material tank 1 for accommodating the liquid material LM by means of the heating device 2, the temperature inside the material tank 1 increases, the vapor pressure of the liquid material LM is increased, and thus the liquid material LM is appropriately evaporated so that a predetermined evaporation gas G is generated. A pressure differential between the material tank 1 and the gas discharge pipe 7 is obtained so that the evaporation gas G is discharged at the desired flow rate to the gas discharge pipe 7. The gas flow meter 8 and the gas flow control valve 9 are provided on the gas discharge pipe 7 in such a manner that they are mutually independent. The gas flow control valve 9, since being heated and kept warm to a temperature about 10° C. higher than the set temperature T° C. of the material tank 1, can sufficiently compensate for the heat loss due to adiabatic expansion, and can regulate the flow rate of the evaporation gas G with a high precision. The gas flow meter 8, since being heated and kept warm to a temperature approximately 5 to 8° C. lower than the that of the gas flow control valve 9, can measure the flow rate of the evaporation gas G with high precision, and thus the evaporation gas G discharged to the gas discharge pipe 7 flows at a predetermined flow rate in a use point direction via the on-off valve 10.

When the amount of the liquid material LM inside the material tank 1 becomes below a predetermined volume, a predetermined signal is sent from the liquid level sensor to the personal computer 14. By this signal input, a predetermined signal is sent from the personal computer 14 to the preheat device 4 and the heating device 6, and these devices perform desired heating operations. The liquid flow regulation device 5 is opened after a predetermined time period elapses so that new heated liquid material LM is supplied to the material tank 1. In this case, since the supplied liquid material LM is heated (preheated) to a predetermined temperature by the preheat device 4 and its amount to be supplied is restricted (regulated) by the liquid flow regulation device 5, the liquid material LM inside the material tank 1 is not prevented from evaporating. That is, even while outside liquid material LM is supplied, the temperature of the liquid material LM inside the material tank 1 does not decrease and it is evaporated by a steady heating rate so that the desired generation of evaporation gas G is maintained.

As described above, in a liquid material evaporation supply apparatus of the above-described structure, since the preheat device 4 for preheating the liquid material LM that is to be supplied to the material tank 1 and the liquid flow regulation device 5 for regulating the flow rate of the liquid material LM are provided on the liquid material supply pipe 3, the liquid material LM which is replenished when the amount of the liquid material LM inside the material tank 1 becomes smaller is preheated before it is supplied. Further, since the amount of supply is controlled so that a desired flow rate is maintained, evaporation inside the material tank 1 is not adversely affected, and the liquid material LM can be supplied even while evaporation gas is being generated. Since the temperatures of the gas flow meter 8 and the gas flow control valve 9 provided on the gas discharge pipe 7 which discharges evaporation gas G are independently controlled so that functions of the respective meter and valve can be given full play to their abilities, evaporation gas G can be measured with high precision and the flow rate thereof can be controlled with high accuracy. Moreover, since the material tank 1 is heated by the heating device 2 exclusively, the temperature can be controlled freely so as to become a temperature by which evaporation of the liquid material LM is performed under an ideal condition.

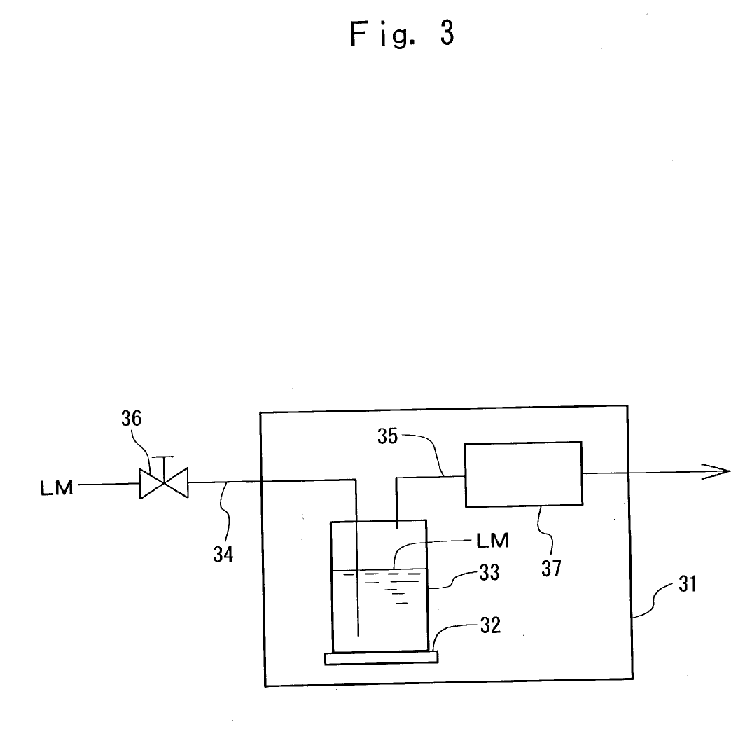

The heating device 2 is provided on the material tank 1, the preheat device 4 is provided on the liquid material supply pipe 3, the heating device 6 is provided on the liquid flow regulation device 5, the heating device 11 is provided on the gas flow meter 8, the heating device 12 is provided on the gas flow control valve 9, and these material tank 1, liquid material supply pipe 3, liquid flow regulation device 5, gas flow meter 8, and gas flow control valve 9 are heated and kept warm so that their temperatures become appropriate values, respectively. Thus, there is no need to provide a thermostatic chamber 31 as shown in FIG. 3, and a compact liquid material evaporation supply apparatus can be constructed.

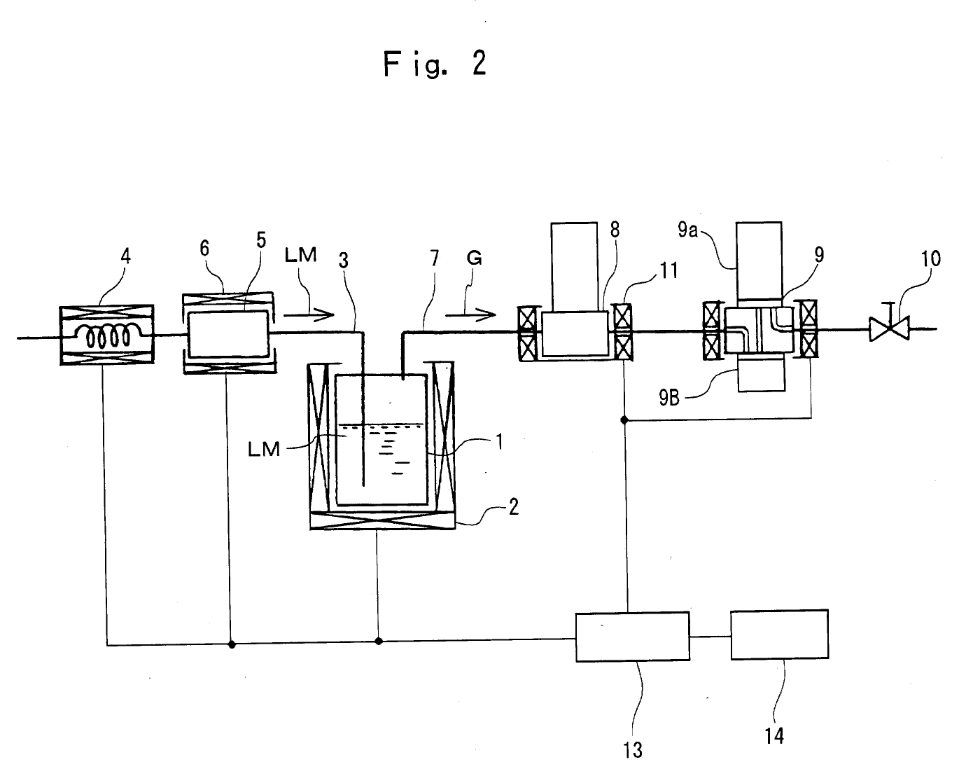

The present invention is not limited to the above-described embodiment, and for example, a pneumatic valve 9B in which a shut off control is possible can be integrally provided may be employed as the gas flow control valve 9 as shown in FIG. 2.

In both the liquid material evaporation supply apparatuses of FIG. 1 and FIG. 2, where a mass flow meter for high temperature service is employed as the gas flow meter 8 and a large diameter capillary is employed as its sensor portion, a pressure loss in the sensor portion can be decreased, miniaturization can be further facilitated, and reliability can be further enhanced by decreasing temperatures.

As the liquid flow regulation device 5, a restriction orifice can be used.

The arrangement of the preheat device 4 and the liquid flow regulation device 5 on the liquid material supply pipe 3 may be reversed with respect to the ones exemplified in the drawings, and the arrangement of the gas flow meter 8 and the gas flow control valve 9 on the gas discharge pipe 7 may be reversed with respect to the ones exemplified in the drawings.

As described above, with a liquid material evaporation supply apparatuses of the present invention, even when supplemental liquid material is supplied to the material tank, appropriate evaporation of the liquid material inside the material tank is not interrupted. Therefore, the liquid material can be evaporated continuously and stably so that desired evaporation gas can be generated, and the flow rate of the generated evaporation gas can be controlled stably with high accuracy. Since there is no need to accommodate the material tank in a thermostatic chamber as in a conventional apparatus, the entire apparatus can be constructed compactly. That is, with the present invention, a compact liquid material evaporation supply apparatus with high reliability can be obtained.

Those skilled in the art will appreciate that various adaptations and modifications of the just-described preferred embodiment(s) can be configured without departing from the scope and spirit of the invention. Therefore, it is to be understood that, within the scope of the appended claims, the invention may be practiced other than as specifically described herein.

What is claimed is:

1. In a liquid material evaporation supply apparatus with a material tank which accommodates a liquid material and in which the liquid material is heated to generate a predetermined gas, a liquid material supply pipe for supplying the liquid material to the material tank, and a gas discharge pipe for discharging the gas generated in the material tank, the improvement comprising:
a heating device for heating exclusively the material tank is provided on the material tank;
a preheat device for preheating the liquid material supplied to the material tank through the liquid material supply pipe; and
a liquid flow regulation device for regulating the flow rate of the liquid material that is to be supplied to the material tank are provided on the liquid material supply pipe.

2. The liquid material evaporation supply apparatus, of claim 1 further including a gas flow meter and a gas flow control valve, both mutually independently provided on the gas discharge pipe, and the temperatures of the gas flow meter and the gas flow control valve are individually controlled.

3. The liquid material evaporation supply apparatus of claim 2 further including a heater device connected to the liquid flow regulation device for maintaining the temperature of the liquid material to a pre-determined temperature.

4. An evaporation supply apparatus for supplying gas to a production line, comprising:
a source of liquid material;
a preheat device for heating the liquid material;
a mass flow controller for receiving the pre-heated liquid material;
a first heater for heating the mass flow controller to a predetermined temperature;
a tank, for evaporating the liquid material to a gas, connected to the mass flow controller;
a second heater for heating the tank;
a gas discharge conduct, connected to the tank;
a gas flow meter connected to the gas discharge unit;
a third heater for heating the gas flow meter; and
a control system connected to the preheat device, first heater, second heater and third heater to monitor and regulate temperatures to provide a constant flow of gas.

5. The evaporation supply apparatus of claim 4 further including a gas flow control valve connected to the gas flow meter and a fourth heater for heating the gas flow control valve.

6. An evaporation supply apparatus for supplying gas from a liquid materialized comprising:
a source of liquid material;
a supply of conduit connected to the source of liquid material;
an evaporation tank connected to the supply conduit;
a mass flow controller connected to the supply conduit to regulate the amount of liquid material flowing through the supply conduit;
a first heater connected to the mass flow controller for maintaining the liquid material at a predetermined temperature;
a second heater connected to the evaporation tank for heating the liquid material to provide a gas;
a gas discharge conduit connected to the evaporation tank;
a gas flow meter connected to the gas discharge conduit for controlling the flow of gas;
a third heater connected to the gas flow meter for heating the gas to a predetermined temperature; and
a controller unit for monitoring the temperature and flow meter to individually set the temperatures of the first heater, second heater and third heater depending on the input of liquid material from the mass flow controller and the output of gas from the gas flow meter.

7. The evaporation supply apparatus of claim 6 further including a pre heater attached to the supply conduit upstream of the mass flow controller and controlled by the controller unit to initially pre-heat the liquid material.
